(19) United States
(12) Patent Application Publication
(10) Pub. No.: US 2021/0399206 A1
(43) Pub. Date: Dec. 23, 2021

(54) PATTERNING OF ORGANIC FILM BY WET ETCHING PROCESS

(71) Applicant: Qualcomm Incorporated, San Diego, CA (US)

(72) Inventors: Shaojui Li, Hsinchu (TW); Wei Hsiang Weng, Hsin-Chu (TW); Min-Lun Yang, Miaoli County (TW); Yi-Fan Su, Sinfong Township (TW)

(21) Appl. No.: 16/946,404

(22) Filed: Jun. 19, 2020

Related U.S. Application Data
(60) Provisional application No. 62/705,269, filed on Jun. 18, 2020.

(51) Int. Cl. H01L 41/332; B06B 1/06; H01L 41/193

(52) U.S. Cl. CPC H01L 41/332; B06B 1/0688; G06K 9/0002; B06B 2201/70; H01L 41/193

(57) ABSTRACT

An organic film is patterned without applying a hard mask or photolithography. A hydrophilic solvent-soluble resist is placed and arranged on the organic film using a non-lithography process. The hydrophilic solvent-soluble resist is placed and arranged using a printing or lamination process. The organic film is patterned using a wet etchant that is selective to the organic film but non-selective to the hydrophilic solvent-soluble resist. The hydrophilic solvent-soluble resist protects the underlying organic film from contamination and damage, prevents undercutting, and assists in providing a desired taper profile during patterning.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in its entirety and for all purposes.

### TECHNICAL FIELD

This disclosure relates generally to patterning materials by wet etching and more particularly to patterning an organic film by wet etching using a hydrophilic solvent-soluble resist.

### DESCRIPTION OF RELATED TECHNOLOGY

In the fabrication of electronic devices, photolithography or optical lithography is often used to selectively remove parts of a thin film layer or part of a substrate. Lithographic processes conventionally use light to transfer a pattern from a photomask to a light-sensitive chemical such as a photoresist on the substrate or other layer. The photomask serves to provide patterns that encode and image to resemble the intended patterns to be created on underlying materials. After exposure to the light, the photoresist may change in composition such that a developer can be applied to remove a portion of the photoresist to form a patterned photoresist. The patterned photoresist can then be used as a mask for etching underlying materials.

Photoresists typically include a polymer or other organic “soft” resist material. Such polymers or soft resist materials tend to be etched easily by highly reactive etchants used in dry or wet etching processes. Hard mask materials are generally more robust and resistant to highly reactive etchants. Conventional lithographic processes may be applied to pattern a hard mask using a patterned photoresist. After forming the patterned hard mask, the patterned photoresist may be removed by stripping. The patterned hard mask can then be used as a mask for etching underlying materials. After etching, the patterned hard mask may be removed.

### SUMMARY

The devices, systems, and methods of this disclosure each have several aspects, no single one of which is solely responsible for the desirable attributes disclosed herein.

One aspect of the subject matter of this disclosure can be implemented in a method of patterning an organic layer of a substrate. The method includes providing a substrate having an organic layer, depositing a water-soluble resist over the organic layer, where the water-soluble resist is deposited by a technique selected from a group consisting of: screen printing, lamination, stencil printing, imprinting, and inkjet printing, and patterning the organic layer by wet etching to form a patterned organic structure, and removing the water-soluble resist using water or water-based solvent.

In some implementations, the organic layer includes a piezoelectric material. The piezoelectric material may include polyvinylidene fluoride (PVDF) polymer or polyvinylidene trifluoroethylene (PVDF-TrFE) copolymer, and where the substrate includes a plurality of thin film transistor (TFT) circuits, the piezoelectric material being positioned over the plurality of TFT circuits. In some implementations, the patterned organic structure has a taper angle between about 5 degrees and about 85 degrees after patterning the organic layer by wet etching. In some implementations, the patterned organic structure has a taper angle between about 30 degrees and about 70 degrees after patterning the organic layer by wet etching. In some implementations, the water-soluble resist adheres to the patterned organic structure after patterning the organic layer by wet etching. In some implementations, the patterned organic structure is free or substantially free of contaminants after patterning the organic layer by wet etching and removing the water-soluble resist. In some implementations, the patterned organic structure is formed without an undercut after patterning the organic layer by wet etching. In some implementations, the method further includes curing the water-soluble resist at an elevated temperature between about 50° C. and about 400° C. and for a duration between about 5 minutes and about 120 minutes prior to patterning the organic layer. In some implementations, the water-soluble resist has an average thickness between about 0.5 μm and about 50 μm. In some implementations, the water-soluble resist is deposited and patterned on the organic layer without applying lithography. In some implementations, the patterned organic structure is formed without applying a hard mask. In some implementations, the water-soluble resist is deposited and patterned on the organic layer by screen printing.

Another innovative aspect of the subject matter described in this disclosure can be implemented in a device. The device includes a substrate having a plurality of TFT circuits, a piezoelectric material coating over the plurality of TFT circuits, where the piezoelectric material coating is patterned by: depositing a water-soluble resist over a piezoelectric layer by a technique selected from a group consisting of: screen printing, lamination, stencil printing, imprinting, and inkjet printing, patterning the piezoelectric layer by wet etching to form the piezoelectric material coating, and removing the water-soluble resist.

In some implementations, the piezoelectric material coating has a taper angle between about 30 degrees and about 70 degrees, is free or substantially free of contaminants, and is formed without an undercut. In some implementations, the piezoelectric material coating is patterned without applying a hard mask or applying photolithography.

### BRIEF DESCRIPTION OF THE DRAWINGS

Details of one or more implementations of the subject matter described in this specification are set forth in the accompanying drawings and the description below. Other features, aspects, and advantages will become apparent from the description, drawings and claims. Note that the relative dimensions of the following figures may not be drawn to scale.

Like reference numbers and designations in the various drawings indicate like elements.

FIG. 1 shows a flow diagram illustrating an example process for patterning an organic layer using hard mask materials and photolithography.

FIGS. 2A-2H show cross-sectional schematics illustrating various stages of an example process of patterning an organic layer using hard mask materials and photolithography.

FIG. 3 shows a flow diagram illustrating an example process for patterning an organic layer using a water-soluble resist according to some implementations.

FIGS. 4A-4F show cross-sectional schematics illustrating various stages of an example process of patterning an organic layer using a water-soluble resist according to some implementations.

FIGS. 5A-5D show cross-sectional schematic views illustrating various stages of an example process of patterning a piezoelectric layer of an ultrasonic sensor system using a water-soluble resist according to some implementations.

FIG. 6A shows a scanning electron microscopy (SEM) image illustrating good adhesion of an example water-soluble resist on an organic film after wet etching.

FIG. 6B shows an exploded view of the SEM image of FIG. 6A.

FIG. 6C shows an SEM image illustrating poor adhesion of an example water-soluble resist on an organic film after wet etching.

FIG. 7A shows an SEM image illustrating an etching profile of 70 degrees for an example organic film after wet etching.

FIG. 7B shows an SEM image illustrating an etching profile of 10 degrees for an example organic film after wet etching.

FIG. 7C shows an SEM image illustrating an etching profile of 87 degrees for an example organic film after wet etching.

FIG. 7D shows an SEM image illustrating an etching profile of greater than 90 degrees with an undercut for an example organic film after wet etching.

FIG. 8A shows an SEM image illustrating good crystalline morphology of an example piezoelectric material surface without residue after wet etching and resist stripping.

FIG. 8B shows an SEM image illustrating crystalline morphology of an example piezoelectric material surface with residue after wet etching and resist stripping.

FIG. 8C shows an SEM image illustrating poor crystalline morphology of an example piezoelectric material surface after wet etching and resist stripping.

FIG. 9 shows a cross-sectional schematic view of an example ultrasonic fingerprint sensor system including a sensor substrate and piezoelectric layer.

FIG. 10 shows a schematic diagram of an example 4×4 pixel array of sensor pixels for an ultrasonic fingerprint sensor system.

FIGS. 11A-11B show example arrangements of ultrasonic transmitters and receivers in example ultrasonic fingerprint sensor systems, with other arrangements being possible.

### DETAILED DESCRIPTION

The following description is directed to certain implementations for the purposes of describing various aspects of this disclosure. However, a person having ordinary skill in the art will readily recognize that the teachings herein can be applied in a multitude of different ways. Various embodiments will be described in detail with reference to the accompanying drawings. References made to particular examples and implementations are for illustrative purposes, and are not intended to limit the scope of the claims.

Organic materials are more commonly being incorporated with developments in electronic devices. Some examples include organic materials serving as organic semiconductors such as organic photovoltaic cells, organic photodetectors, organic thin-film transistors, and organic light-emitting diodes. Other examples include organic materials in flexible circuits and display devices. Furthermore, some organic materials may be piezoelectric materials that serve as transmitters/receivers in an electronic device.

One of the challenges in device fabrication may involve patterning of organic layers. Effective patterning of organic layers may be limited by currently available patterning techniques. Conventionally, using a photolithographic process with organic materials is not straightforward, as many of the solvents used with standard photoresists, as well as solvents used for resist development and/or resist stripping, may dissolve the organic materials. Accordingly, inorganic hard masks may be applied for patterning the organic materials, where the inorganic hard masks are ordinarily patterned by photolithographic processes.

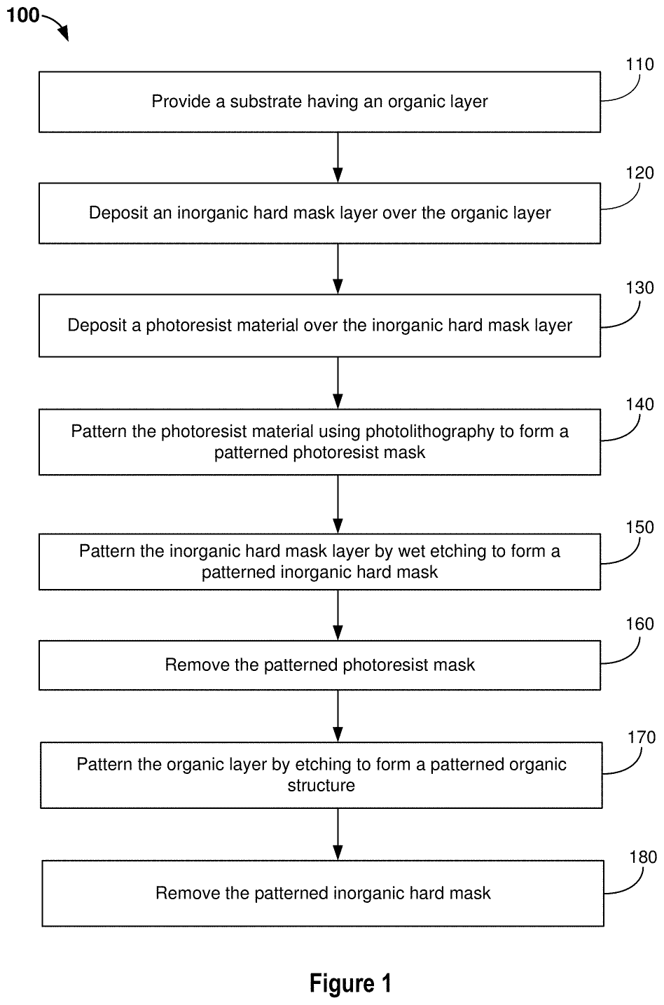

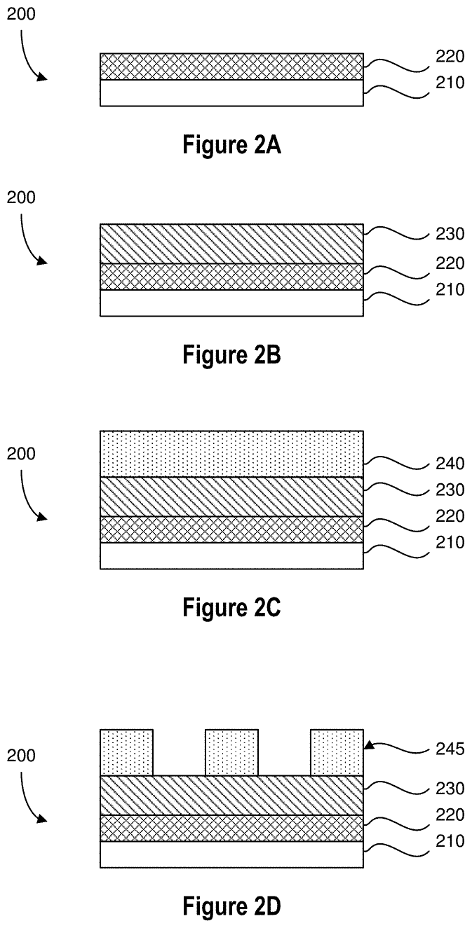

FIG. 1 shows a flow diagram illustrating an example process for patterning an organic layer using hard mask materials and photolithography. A process 100 may be performed in a different order or with additional operations. Aspects of the process 100 are described with respect to FIGS. 2A-2H.

At block 110 of the process 100, a substrate is provided having an organic layer. The substrate may be made from any suitable substrate material. In some implementations, the substrate can be made of plastic, glass, silicon, stainless steel, or other suitable substrate material. In some implementations, the substrate is a glass substrate, where examples of glass substrate materials include borosilicate glass, soda lime glass, quartz, Pyrex®, or other suitable glass material. In some implementations, the substrate is a plastic substrate, where examples of plastic substrate materials include acrylic, polycarbonate, polyethylene terephthalate (PET), polyethylene (PEN), or polyimide. In some implementations, the substrate is a flexible substrate, where the flexible substrate material can include PET, PEN, polyimide, stainless steel foil, thin film silicon, or other flexible material. In some implementations, the substrate is a non-flexible substrate, where the non-flexible substrate material can include glass, silicon, or ceramic. In some implementations, the substrate may include a plurality of sensor circuits disposed thereon. Such a substrate may be referred to as a “sensor substrate.”

In some implementations, the organic layer includes a piezoelectric layer. For example, the piezoelectric layer includes a piezoelectric polymer material such as polyvinylidene fluoride (PVDF) or polyvinylidene fluoride trifluoroethylene (PVDF-TrFE) copolymer. Other examples of piezoelectric polymer materials that may be utilized include polyvinylidene chloride (PVDC) homopolymers and copolymers, polytetrafluoroethylene (PTFE) homopolymers and copolymers, and diisopropylammonium bromide (DIPAB). In some implementations, the piezoelectric layer may be coupled to the substrate having the plurality of sensor circuits. The piezoelectric layer may be configured to generate acoustic waves such as ultrasonic waves. The organic layer may be positioned over the substrate. In some implementations, the organic layer may be deposited over the substrate to cover an entirety or a substantial entirety of a surface of the substrate. In some implementations, the organic layer may be deposited using a spin-coating technique or conformal coating technique. The organic layer may be non-patterned and deposited conformally over one or more features of the substrate.

FIG. 2A shows a cross-sectional schematic of a partially fabricated device 200 illustrating an organic layer 220 positioned over a substrate 210. The organic layer 220 may be provided over the substrate 210 by blanket deposition using a technique such as spin-coating or a conformal coating technique. The organic layer 220 may be provided on the substrate 210 without patterning. As used herein, the organic layer 220 may also be referred to as an organic film, organic coating, non-patterned organic coating, conformal organic coating, or non-patterned conformal organic coating. The organic layer 220 may be relatively thin and have a thickness between about 2 μm and about 40 μm, between about 3 μm and about 30 μm, or between about 5 μm and about 20 μm. The organic layer 220 may be In some implementations, the substrate 210 may be any suitable substrate including silicon wafers, glass substrates, silicon substrates with integrated circuitry, thin film transistor (TFT) substrates, display substrates such as liquid crystal display (LCD) or organic light emitting diode (OLED) display substrates, or plastic substrates. In some implementations, the organic layer 220 includes a piezoelectric polymer material such as PVDF or PVDF-TrFE copolymer.

Returning to FIG. 1, at block 120 of the process 100, an inorganic hard mask layer is deposited over the organic layer. Examples of inorganic hard mask materials include but are not limited to silicon nitride, silicon oxide, silicon carbonitride, silicon oxycarbide, silicon oxynitride, amorphous silicon, or polysilicon. Other examples of inorganic hard mask materials may include one or more metals, where the inorganic hard mask material may include tungsten oxide, tungsten nitride, tungsten carbide, or titanium nitride. The inorganic hard mask layer may be deposited on the organic layer using any suitable deposition technique such as chemical vapor deposition (CVD), plasma-enhanced chemical vapor deposition (PECVD), or atomic layer deposition (ALD).

FIG. 2B shows a cross-sectional schematic of the partially fabricated device 200 illustrating an inorganic hard mask layer 230 positioned over the organic layer 220. The inorganic hard mask layer 230 may be provided over the organic layer 220 by blanket deposition and without patterning. In some implementations, the inorganic hard mask layer 230 includes a silicon-containing hard mask material or metal-containing hard mask material. For example, the inorganic hard mask layer 230 includes doped or undoped silicon nitride, doped or undoped silicon oxide, amorphous silicon, polysilicon, tungsten oxide, tungsten nitride, tungsten carbide, or titanium nitride.

Returning to FIG. 1, at block 130 of the process 100, a photoresist material is deposited over the inorganic hard mask layer. The photoresist material may be a photopatternable resist made of organic materials. In some implementations, the photoresist material may be a hydrophobic solvent-soluble photoresist, meaning that the photoresist material may be resistant to dissolution by pure water but soluble in other solvents such as organic solvents or an aqueous solution of an inorganic base. The photoresist material may be deposited on the inorganic hard mask layer using any suitable deposition technique such as spin-on deposition or dry vapor deposition (e.g., CVD, PECVD, or ALD).

FIG. 2C shows a cross-sectional schematic of the partially fabricated device 200 illustrating a photoresist material 240 positioned over the inorganic hard mask layer 230. The photoresist material 240 may be provided over the inorganic hard mask layer 230 by blanket deposition and without patterning. In some implementations, the photoresist material 240 includes a photopatternable resist made of organic materials.

Returning to FIG. 1, at block 140 of the process 100, the photoresist material is patterned using photolithography to form a patterned photoresist mask. Patterns are printed onto the photoresist material by passing photons through a reticle from a photon source. The reticle may be a glass plate that is patterned with feature geometries that block photons from propagating through the reticle. After passing through the reticle, the photons contact the surface of the photoresist material and changes the chemical composition of the photoresist material. A developer is applied to the photoresist material to remove portions of the photoresist material, thereby leaving a patterned photoresist mask over the inorganic hard mask layer.

FIG. 2D shows a cross-sectional schematic of the partially fabricated device 200 illustrating a patterned photoresist mask 245 over the inorganic hard mask layer 230. The patterned photoresist mask 245 may be obtained by patterning the photoresist material 240 using photolithography. Portions of the photoresist material 240 are removed during photolithography, and the patterned photoresist mask 245 remains to serve as a mask for the underlying inorganic hard mask layer 230.

Returning to FIG. 1, at block 150 of the process 100, the inorganic hard mask layer is patterned by wet etching to form a patterned inorganic hard mask. An example wet etchant used in wet etching may be, for example, dilute hydrofluoric acid (HF). The wet etchant may selectively remove portions of the inorganic hard mask layer defined by the patterned photoresist mask. The wet etchant may selectively remove the portions of the inorganic hard mask layer without removing the patterned photoresist mask or the underlying organic layer. Wet etching using the patterned photoresist mask forms a desired arrangement of features in the patterned inorganic hard mask.

FIG. 2E shows a cross-sectional schematic of the partially fabricated device 200 after forming a patterned inorganic hard mask 235 by wet etching. Wet etching opens up portions of the inorganic hard mask layer 230 defined by the patterned photoresist mask 245. A wet etchant is selective to the inorganic hard mask layer 230 but non-selective to the patterned photoresist mask 245 and the underlying organic layer 220. A pattern of the patterned inorganic hard mask 235 matches a pattern of the patterned photoresist mask 245 after wet etching.

Returning to FIG. 1, at block 160 of the process 100, the patterned photoresist mask is removed. The patterned photoresist mask may be removed using a stripping process. In some implementations, the stripping process may be followed by a substrate rinsing process to ensure complete removal of photoresist material from the substrate. In some implementations, the substrate rinsing process may use pure water. The patterned inorganic hard mask may remain after removal of the patterned photoresist mask.

FIG. 2F shows a cross-sectional schematic of the partially fabricated device 200 after removal of the patterned photoresist mask 245 from the substrate 210. A wet or dry stripping process may be applied to remove the patterned photoresist mask 245, and a substrate rinsing process may follow to ensure complete removal of the patterned photoresist mask 245. The corresponding patterned inorganic hard mask 235 remains after the wet or dry stripping process.

Returning to FIG. 1, at block 170 of the process 100, the organic layer is patterned by etching to form a patterned organic structure. In some implementations, the organic layer is patternable using a wet etchant such as a pure or hybrid hydrophobic wet etchant. In other words, the wet etchant may be a single solvent or a mixture of solvents for patterning the organic layer. It will be understood that a hydrophobic wet etchant shares the same polarity or polar behavior as the organic layer (e.g., if the organic layer is hydrophobic, then the wet etchant is selected as hydrophobic). In some implementations, the wet etchant may include acetone, methyl ethyl ketone (MEK), glycol ethers, glycol ether esters such as propylene glycol methyl ether acetate (PGMEA), dimethyl acetamide (DMAc), dimethyl sulfoxide (DMSO), water, or combinations thereof. The organic layer may be dissolved during wet etching using a specific solvent or mixture of solvents. In some implementations, a mixture of solvents may be applied to form a tapered profile during etching. Etchant formulations or etchant conditions such as time, temperature, and/or pressure may be varied to control a taper profile of the patterned organic structure. The wet etchant may selectively remove portions of the organic layer defined by the patterned inorganic hard mask. The wet etchant may selectively remove the portions of the organic layer without removing the patterned inorganic hard mask or the underlying substrate. Wet etching using the patterned inorganic hard mask forms a desired arrangement of features in the patterned organic structure.

FIG. 2G shows a cross-sectional schematic of the partially fabricated device 200 after forming a patterned organic structure 225 by wet etching. Wet etching removes portions of the organic layer 220 defined by the patterned inorganic hard mask 235. A wet etchant is selective to the organic layer 220 but non-selective to the patterned inorganic hard mask 235 and the underlying substrate 210. The wet etchant may include a single solvent or a combination of solvents. Etchant formulations or etchant conditions may be varied to control a taper profile of the patterned organic structure 225.

Returning to FIG. 1, at block 180 of the process 100, the patterned inorganic hard mask is removed. The patterned inorganic hard mask may be removed using a dry or wet etchant, and a substrate rinsing process may follow to ensure complete removal of patterned inorganic hard mask. For example, the dry or wet etchant may include a fluorine-containing reagent such as hydrofluoric acid. The corresponding patterned organic structure remains on the substrate after removing the patterned inorganic hard mask.

FIG. 2H shows a cross-sectional schematic of the partially or completely fabricated device 200 after removing the patterned inorganic hard mask 235 from the substrate 210. A dry or wet etchant may be applied to selectively remove the patterned inorganic hard mask 235, and a substrate rinsing process may follow to ensure complete removal of the patterned inorganic hard mask 235. The corresponding patterned organic structure 225 remains on the substrate 210 after the removal process.

As shown by FIG. 1 and corresponding FIGS. 2A-2H, patterning an organic layer to form patterned organic features on a substrate may involve several operations that are cumbersome, time-consuming, and costly. Such operations my limit integration in tool platforms and reduce throughput. Conventional patterning processes of organic materials may utilize: (1) hard mask patterning processes that involve hard mask deposition, patterning, and removal and (2) photolithography processes that involve photoresist deposition, patterning (e.g., exposing and developing), and stripping.

The present disclosure relates to patterning an organic layer or organic coating without hard mask patterning processes and without photolithography processes. A hydrophilic solvent-soluble resist is placed on the organic layer, where the hydrophilic solvent-soluble resist may be a water-soluble resist. The hydrophilic solvent-soluble resist is placed and arranged on the organic layer by a non-lithography process. For example, such placement and arrangement occur by screen printing, lamination, stencil printing, imprinting, or inkjet printing. The organic layer is patterned using a wet etchant to remove portions of the organic layer to form a patterned organic structure. The hydrophilic solvent-soluble resist is subsequently removed. The hydrophilic solvent-soluble resist maintains adhesion to the organic layer when patterning the organic layer, which can provide a desired taper profile for the patterned organic structure. In addition, the hydrophilic solvent-soluble resist limits damage and contamination of the patterned organic structure.

Particular implementations of the subject matter described in this disclosure may be implemented to realize one or more of the following potential advantages. Patterning of an organic layer is performed with fewer steps by selection and placement of a hydrophilic solvent-soluble resist. Rather than steps of photoresist deposition, exposing, development, and stripping along with hard mask deposition, patterning, and removal, the patterning process of the present disclosure significantly reduces the number of steps in patterning an organic layer by employing steps of hydrophilic solvent-soluble resist placement and removal. This reduces the cost of device fabrication by avoiding lithography processes, extra photoresist stripping processes, and hard mask patterning processes. With fewer steps for patterning, such steps may be implementable for mass production in a large-scale tool platform, thereby simplifying production. Furthermore, this increases throughput and product capacity. The use of a hydrophilic solvent-soluble resist additionally provides environmental benefits because removal of the hydrophilic solvent-soluble resist does not pose environmental hazards.

As used herein, the term “hydrophilic solvent-soluble resist” may be used interchangeably with “water-soluble resist.” Though not necessarily all hydrophilic solvent-soluble resists are soluble in pure water, such resists are generally soluble in water and so may be referred to as a “water-soluble resist” for simplicity.

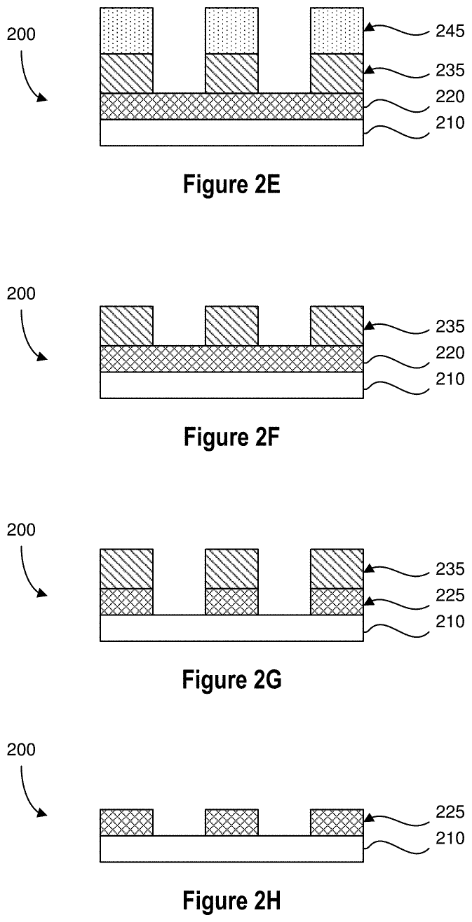

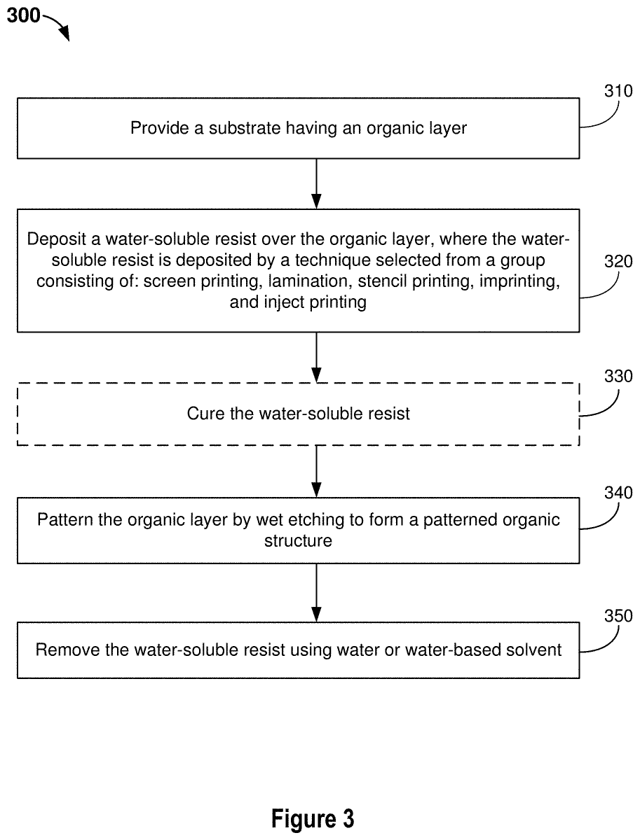

FIG. 3 shows a flow diagram illustrating an example process for patterning an organic layer using a water-soluble resist according to some implementations. A process 300 may be performed in a different order with different, fewer, or additional operations. In some implementations, the blocks of the process 300 may be implemented, at least in part, according to software stored on one or more non-transitory computer readable media. Aspects of the process 300 are described with respect to FIGS. 4A-4F.

At block 310 of the process 300, a substrate is provided having an organic layer. The substrate may be made from any suitable substrate material. In some implementations, the substrate can be made of plastic, glass, silicon, stainless steel, or other suitable substrate material. In some implementations, the substrate is a glass substrate, where examples of glass substrate materials include borosilicate glass, soda lime glass, quartz, Pyrex®, or other suitable glass material. In some implementations, the substrate is a plastic substrate, where examples of plastic substrate materials include acrylic, polycarbonate, PET, PEN, or polyimide. In some implementations, the substrate is a flexible substrate, where the flexible substrate material can include PET, PEN, polyimide, stainless steel foil, thin film silicon, or other flexible material. In some implementations, the substrate is a non-flexible substrate, where the non-flexible substrate material can include glass, silicon, or ceramic. In some implementations, the substrate may include a plurality of sensor circuits disposed thereon. Such a substrate may be referred to as a “sensor substrate.”

In some implementations, the organic layer includes a piezoelectric layer. For example, the piezoelectric layer includes a piezoelectric polymer material such as PVDF or PVDF-TrFE copolymer. Other examples of piezoelectric polymer materials that may be utilized include PVDC homopolymers and copolymers, PTFE homopolymers and copolymers, and DIPAB. In some implementations, the piezoelectric layer may be coupled to the substrate having the plurality of sensor circuits. The piezoelectric layer may be configured to generate acoustic waves such as ultrasonic waves. The organic layer may be positioned over the substrate. In some implementations, the organic layer may be deposited over the substrate to cover an entirety or a substantial entirety of a surface of the substrate. In some implementations, the organic layer may be deposited using a spin-coating technique or conformal coating technique. The organic layer may be non-patterned and deposited conformally over one or more features of the substrate.

FIG. 4A shows a cross-sectional schematic of a partially fabricated device 400 illustrating an organic layer 420 positioned over a substrate 410. The organic layer 420 may be provided over the substrate 410 by blanket deposition using a technique such as spin-coating or a conformal coating technique. The organic layer 420 may be provided on the substrate 410 without patterning. The organic layer 420 may be relatively thin and have a thickness between about 2 μm and about 40 μm, between about 3 μm and about 30 μm, or between about 5 μm and about 20 μm. The organic layer 420 may be In some implementations, the substrate 410 may be any suitable substrate including silicon wafers, glass substrates, silicon substrates with integrated circuitry, thin film transistor (TFT) substrates, display substrates such as liquid crystal display (LCD) or organic light emitting diode (OLED) display substrates, or plastic substrates. In some implementations, the organic layer 420 includes a piezoelectric polymer material such as PVDF or PVDF-TrFE copolymer.

Returning to FIG. 3, at block 320 of the process 300, a water-soluble resist is deposited over the organic layer, where the water-soluble resist is deposited by a technique selected from a group consisting of: screen printing, lamination, stencil printing, imprinting, and inkjet printing. The water-soluble resist is applied on the organic layer according to a predetermined pattern using a printing or lamination process. The water-soluble resist is placed and arranged to serve as a mask for defining a pattern in the underlying organic layer. Unexposed portions of the organic layer are covered by the water-soluble resist while exposed portions of the organic layer are not. Ordinarily, water-soluble resists are placed and patterned using a traditional lithography process instead of a printing or lamination process. Or, water-soluble resists are placed and patterned as protective layers in automotive, architectural, paint, textile, cosmetic, and other industrial applications. Such water-soluble resists typically do not function as masks for patterning underlying layers.

The water-soluble resist may have a desired composition and may be deposited under certain conditions to ensure several criteria are met in patterning the organic layer. The water-soluble resist is selected and deposited to protect the organic layer from contamination. For example, the water-soluble resist prevents or otherwise limits formation of unwanted residues that are prone to form due to reactions caused by the water-soluble resist, organic layer, wet etchant, and/or stripper. Moreover, the water-soluble resist is selected and deposited to prevent or otherwise minimize damage to the underlying organic layer after wet etching and stripping. The water-soluble resist is also selected and deposited to provide a strong adhesion interface between the water-soluble resist and the organic layer. That way, the water-soluble resist prevents undercutting in the organic layer due to lateral etching at the interface. In some implementations, the water-soluble resist is selected and deposited to promote a tapered angle etch during wet etching to form a desired taper profile in the organic layer.

A formulation of the water-soluble resist may be chosen for optimal patterning of the organic layer. In some implementations, the water-soluble resist includes one or more water-soluble polymers. Water-soluble polymers have functional groups that are hydrophilic or that can be functionalized to produce hydrophilic groups. For example, examples of water-soluble polymers include but are not limited to polyvinyl alcohol (PVOH), polyethylene glycol (PEG), polyethylene oxide (PEO), and polyvinyl acetate (PVA). Such water-soluble polymers may be synthesized or formed as a water-soluble resin, where examples of water-soluble resins include but are not limited to POLYOX™ manufactured and made available by Dow Chemical based in Midland, Mich., POVAL™ manufactured and made available by Kuraray based in Tokyo, Japan, and HogoMax003 manufactured and made available by DISCO Corporation based in Tokyo, Japan. The concentration of the one or more water-soluble polymers in the water-soluble resist may be between about 1 wt. % and about 99 wt. %, between about 3 wt. % and about 90 wt. %, or between about 5 wt. % and about 80 wt. %, where the term “about” with respect to the concentration of water-soluble resist throughout this disclosure refers to values within plus or minus 5 percent of the stated value.

In some implementations, the water-soluble resist includes a filler. The filler may serve as a thickening agent to influence a viscosity of the water-soluble resist. The ability to perform a printing operation such as screen printing of the water-soluble resist may depend at least in part on controlling the viscosity of the water-soluble resist. In some implementations, the filler includes silica or carbon-based fillers. The concentration of the filler in the water-soluble resist may be between about 0 wt. % and about 30 wt. %, between about 0.5 wt. % and about 30 wt. %, between about 1 wt. % and about 20 wt. %, or between about 2 wt. % and about 15 wt. %.

In some implementations, the water-soluble resist includes an inorganic salt. In some implementations, the inorganic salt may enhance the solubility of the water-soluble resist for ease of removal. Examples of inorganic salts include but are not limited to alkaline salts and acid salts. The concentration of the inorganic salt in the water-soluble resist may be between about 0 wt. % and about 30 wt. %, between about 0.5 wt. % and about 30 wt. %, between about 1 wt. % and about 20 wt. %, or between about 2 wt. % and about 15 wt. %.

In some implementations, the water-soluble resist includes a surfactant. In some implementations, the surfactant improves wetting of the water-soluble resist to the surface of the organic layer. The surfactant provides good wetting characteristics to the surface of the organic layer without bonding to the surface of the organic layer that would make it too difficult for the water-soluble resist to be removed. Examples of surfactants include but are not limited to alkylsulfates such as NaC₆H₁₃SO₄, polyoxyethylene (4) nonylphenyl ether, alcohol ethoxylates and propoxylates, nonethylene glycol, polyethylene glycol nonyl phenyl ether, polyethoxylated tallow amine, and polyvinyl acetate. The concentration of the surfactant in the water-soluble resist may be between about 0 wt. % and about 30 wt. %, between about 0.5 wt. % and about 30 wt. %, between about 1 wt. % and about 20 wt. %, or about 2 wt. % and about 15 wt. %.

In some implementations, the water-soluble resist includes a thixotropy promoter. The thixotropy promoter influences the thixotropic properties of the water-soluble resist. Examples of thixotropy promoters include but are not limited to CAB-O-SIL® H-300 which is a high surface area fumed silica from Cabot Corporation in Boston, Mass.; KRATON™ G1701 which is a styrene-ethylene-propylene (SEP) polymer with a di-block structure from Kraton Corporation in Houston, Tex.; Arbocarb® 7000C; and Atomite® which is a calcium carbonate from Imerys S.A. in Paris, France. The concentration of the thixotropic promoter in the water-soluble resist may be between about 0 wt. % and about 30 wt. %, between about 0.5 wt. % and about 30 wt. %, between about 1 wt. % and about 20 wt. %, or between about 2 wt. % and about 15 wt. %.

The water-soluble resist includes a carrier liquid that serves as a solvent for one or more the aforementioned components. In some implementations, the one or more water-soluble polymers, the filler, the inorganic salt, the surfactant, surfactant, and/or the thixotropy promoter are soluble in the carrier liquid. Examples of carrier liquids include but are not limited to water, pure solvents such as methanol, ethanol, and acetone, co-solvents such as water and ethanol or other suitable co-solvent, and inorganic solvents. The concentration of the carrier liquid in the water-soluble resist may be between about 1 wt. % and about 99 wt. %, between about 5 wt. % and about 95 wt. %, or between about 10 wt. % and about 90 wt. %.

In some implementations, the water-soluble resist is deposited over the organic layer by screen printing. Screen printing, for example, generally uses flowable mediums with viscosities of hundreds or thousands of centipoise. In screen printing, the flowable medium is forced through a mesh (e.g., polymer or stainless steel mesh) using a blade or squeegee. In some implementations, the water-soluble resist is deposited over the organic layer by lamination. Heat and/or pressure may be applied to laminate the water-soluble resist on the organic layer according to a predetermined pattern. In some implementations, the water-soluble resist is deposited over the organic layer by stencil printing. In stencil printing, a stencil or other type of mask is positioned over the surface of the organic layer, and a paste is applied through stencil apertures to form a pattern of the water-soluble resist on the organic layer. In some implementations, the water-soluble resist is deposited over the organic layer by imprinting. With imprinting, water-soluble resist material is dispensed over the organic layer, where the water-soluble resist material is brought into soft contact with a mold. After application of pressure and temperature, the mold is removed to leave an imprinted pattern of the water-soluble resist on the organic layer. In some implementations, the water-soluble resist is deposited over the organic layer by inkjet printing. Applying the water-soluble resist using printing or lamination processes is achieved without undergoing lithography processes.

FIG. 4B shows a cross-sectional schematic of a partially fabricated device 400 illustrating a water-soluble resist 430 deposited over an organic layer 420. The water-soluble resist 430 is placed and arranged over the organic layer 420 using a printing or lamination technique. In some implementations, the water-soluble resist 430 is placed and arranged according to a predetermined pattern over the organic layer 420 by screen printing. A thickness and composition of the water-soluble resist 430 may be optimized for protecting the organic layer 420 during wet etching and stripping from damage and contamination. In addition, the thickness and composition of the water-soluble resist 430 may be optimized for preventing undercutting and providing a certain tapered profile in the organic layer 420 after wet etching and stripping. The water-soluble resist 430 includes one or more water-soluble polymers such as PVOH, PEG, PEO, and PVA. The water-soluble resist 430 further includes a carrier liquid such as water or inorganic solvent. In some implementations, the water-soluble resist 430 further includes a filler, an inorganic salt, a surfactant, and/or a thixotropy promoter.

Returning to FIG. 3, at block 330 of the process 300, the water-soluble resist is optionally cured. When curing the water-soluble resist, heat and/or radiation may be delivered to the water-soluble resist. In some implementations, heat is delivered as conductive heat using a hot plate or oven. In some implementations, heat is delivered as convective heat using a convection oven, hot gas flow, or blow dryer. In some implementations, the water-soluble resist is exposed to an elevated temperature during curing, where the elevated temperature is between about 50° C. and about 400° C., between about 100° C. and about 350° C., or between about 150° C. and about 300° C. When the water-soluble resist is deposited as a flowable medium, curing serves to dry and harden the water-soluble resist. After curing, the water-soluble resist may have desired properties as a mask for patterning the organic layer. In some implementations, the water-soluble resist has an average thickness between about 0.5 μm and about 50 μm, between about 1 μm and about 30 μm, or between about 2 μm and about 20 μm after curing.

FIG. 4C shows a cross-sectional schematic of a partially fabricated device 400 illustrating the water-soluble resist 430 being exposed to a thermal cure 440. The thermal cure 440 may dry and harden the water-soluble resist 430. The thermal cure 440 exposes the water-soluble resist to an elevated temperature. The thermal cure 440 may utilize conductive heat to deliver thermal energy for curing the water-soluble resist 430. In some implementations, the thermal cure 440 is performed using a hot plate or oven. For example, the water-soluble resist 430 is exposed to the thermal cure 440 at a temperature between about 100° C. and about 350° C. for a duration between about 5 minutes and about 120 minutes.

Returning to FIG. 3, at block 340 of the process 300, the organic layer is patterned by wet etching to form a patterned organic structure. In some implementations, the organic layer is patternable using a wet etchant such as a pure or hybrid hydrophobic wet etchant. Accordingly, the wet etchant may be a single solvent or mixture of solvents for patterning the organic layer. Though the water-soluble resist is removable by water or water-based solvent, the water-soluble resist is resistant a chemistry of the wet etchant. Though the organic layer is removable by the wet etchant during etching, the organic layer is resistant to water or water-based solvent during stripping. The wet etchant may be characterized as hydrophobic. In some implementations, the wet etchant may include acetone, MEK, glycol ethers, glycol ether esters such as PGMEA, DMAc, DMSO, water (i.e., non-warm water), or combinations thereof. The organic layer may be dissolved during wet etching using a specific solvent or mixture of solvents. In some implementations, a mixture of solvents may be applied to form a tapered profile during etching. Etchant formulations or etchant conditions such as time, temperature, and/or pressure may be varied to control a taper profile of the patterned organic structure. The wet etchant may selectively remove portions of the organic layer defined by the water-soluble resist. The wet etchant may selectively remove the portions of the organic layer without removing the water-soluble resist. Wet etching using the water-soluble resist forms a desired arrangement and profile of features in the patterned organic structure.

An etch selectivity of the organic layer is substantially higher than an etch selectivity of the water-soluble resist during wet etching. The organic layer etches at a substantially faster rate than the water-soluble resist when exposed to the wet etchant, where an etch rate of the organic layer is at least 10 times, at least 20 times, or at least 30 times greater than an etch rate of the water-soluble resist. The water-soluble resist exhibits strong chemical resistance to the wet etchant. Thus, the water-soluble resist prevents contamination and damage to unexposed portions of the organic layer while facilitating removal of exposed portions of the organic layer.

The single solvent or mixture of solvents used in wet etching produces a desired taper when patterning the patterned organic structure from the organic layer. Etch process conditions and etch formulation may be selected to achieve a tapered profile in the patterned organic structure. During wet etching, wet etchant removes more material from the organic layer near a top surface of the organic layer than near a bottom surface of the organic layer. As a result, a tapered profile is formed. In some implementations, the patterned organic structure has a taper angle between about 5 degrees and about 85 degrees, between about 10 degrees and about 80 degrees, between about 20 degrees and about 75 degrees, or between about 30 degrees and about 70 degrees after patterning the organic layer by wet etching. The tapered profile in the patterned organic structure is obtained without undercutting. The water-soluble resist strongly adheres to the organic layer during wet etching and does not peel off. Strong interface adhesion between the water-soluble resist and the organic layer provides reliable patterning and prevents undercutting due to lateral etching at the interface.

In some implementations, wet etching is delivered via a spray nozzle. The spray nozzle may be positioned in an etch chamber to supply wet etchant to the substrate. Various etch conditions may be controlled to influence an etch profile of the organic layer. It will be understood that the etch conditions may affect other etch characteristics: erosion of water-soluble resist, faceting, undercutting, relative etch rates, and etch uniformity, among other characteristics. Examples of etch conditions that can be controlled include but are not limited to temperature, time, and pressure. In some implementations, a temperature of the wet etching may be controlled. For example, the wet etching may be heated to a temperature between about 20° C. and about 200° C., between about 50° C. and about 150° C., or between about 70° C. and about 120° C. In some implementations, the substrate may be rotated on a substrate support while wet etchant is delivered to the substrate. In some implementations, a duration of exposure may be controlled. For example, a duration of exposure to wet etching is between about 1 second and about 1000 seconds. In some implementations, a pressure in the etch chamber may be controlled. The pressure in the etch chamber may be relatively low. For example, a pressure in the etch chamber may be between about 1×10⁻⁵ Torr and about 3800 Torr.

FIG. 4D shows a cross-sectional schematic of a partially fabricated device 400 after forming a patterned organic structure 425 by wet etching. Wet etching removes portions of the organic layer 420 defined by the water-soluble resist 430. The substrate 410 is exposed to a wet etchant 450. The wet etchant 450 is selective to the organic layer 420 but non-selective to the water-soluble resist 430 and the underlying substrate 410. The wet etchant 450 may include a single solvent or a combination of solvents. Etchant formulations or etchant conditions may be varied to control a taper profile of the patterned organic structure 425. In some implementations, a taper angle of the patterned organic structure 425 is between about 5 degrees and about 85 degrees. During exposure to the wet etchant 450, the water-soluble resist 430 adheres to the patterned organic structure 425, maintains chemical resistance to prevent damage or contamination to the patterned organic structure 425, and prevents undercutting to the patterned organic structure 425.

Returning to FIG. 3, at block 350 of the process 300, the water-soluble resist is removed using water or water-based solvent. The water-soluble resist may be removed using a stripping process. The stripping process may be characterized by application of pure or hybrid hydrophilic solvent. A stripper for removal of the water-soluble resist may be a single solvent (e.g., water) or a mixture of solvents. Though the patterned organic structure is removable by a pure or hydrophobic wet etchant, the patterned organic structure is resistant to a chemistry of the stripper. Though the water-soluble resist is removable by the stripper, the water-soluble resist is resistant to pure or hydrophobic wet etchant during wet etching. The stripper may be characterized as hydrophilic. In some implementations, the stripper includes water, alkaline water, ethanol, acetone, or mixtures thereof. The patterned organic structure is not removed during stripping. In some implementations, the stripping process may be followed by a substrate rinsing process to ensure complete removal of the water-soluble resist from the substrate. In some implementations, the substrate rinsing process may use pure water and may constitute the stripping process for removal of the water-soluble resist. The stripper is generally environmentally friendly and non-toxic.

In some implementations, the patterned organic structure is free or substantially free of contaminants after removal of the water-soluble resist, where the term “substantially free” throughout this disclosure refers to a concentration of contaminants of less than 1 wt. % in the patterned organic structure. Such contaminants may include unwanted residue left by the water-soluble resist. Stripping conditions of temperature, time, and/or pressure may be varied to ensure complete removal of the water-soluble resist and to limit contamination or damage to the patterned organic structure. In some implementations, removing the water-soluble resist occurs by using water at a temperature between about 20° C. and about 200° C., between about 50° C. and about 150° C., or between about 70° C. and about 120° C.

FIG. 4E shows a cross-sectional schematic of a partially fabricated device 400 after removal of the water-soluble resist 430 by stripping. A wet stripping process may be applied to remove the water-soluble resist 430 from the substrate 410. The water-soluble resist 430 may be removed using water 460. Exposure to water 460 may be part of a substrate rinsing process as well as the wet stripping process. The corresponding patterned organic structure 425 remains after the wet stripping process.

Returning to FIG. 3, in some implementations, the process 300 further includes drying the substrate. This removes moisture from the patterned organic structure as well as the substrate. In some implementations, drying the substrate occurs by conductive heating using a hot plate or oven.

FIG. 4F shows a cross-sectional schematic of a partially or completely fabricated device 400 after drying the substrate 410. The substrate 410 may be exposed to a heat source 470 for removing moisture from the substrate 410 and the patterned organic structure 425. In some implementations, the heat source 470 includes a hot plate or oven. In some implementations, the heat source 470 applies an elevated temperature between about 50° C. and about 400° C., between about 100° C. and about 350° C., or between about 150° C. and about 300° C. to the substrate 410.

As shown by FIG. 3 and corresponding FIGS. 4A-4F, patterning an organic layer to form patterned organic features on a substrate may involve fewer operations that are simpler, less costly, less time-consuming, and more environmentally-friendly compared to operations in FIG. 1 and corresponding FIGS. 2A-2H. An electronic device may be fabricated having one or more patterned organic coatings after performing operations in FIG. 3 and FIGS. 4A-4F. The one or more patterned organic coatings may be patterned piezoelectric coatings.

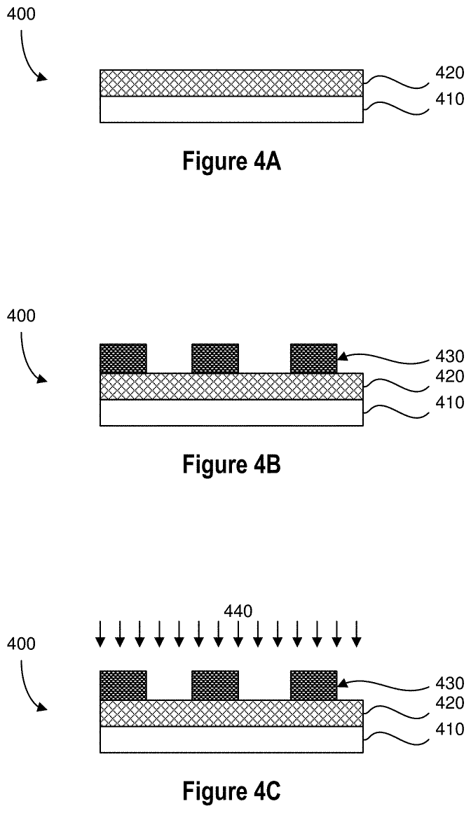

FIGS. 5A-5D show cross-sectional schematic views illustrating various stages of an example process of patterning a piezoelectric layer of an ultrasonic sensor system using a water-soluble resist according to some implementations.

In FIG. 5A, a partially fabricated device 500 includes a substrate 510 having circuitry 520, where the circuitry 520 includes a plurality of TFT circuits 525. The partially fabricated device 500 further includes a piezoelectric layer 530 positioned over the plurality of TFT circuits 525. The piezoelectric layer 530 is an organic film that is conformal over the plurality of TFT circuits 525 and non-patterned.

In FIG. 5B, a water-soluble resist 540 is formed over the piezoelectric layer 530 in the partially fabricated device 500. The water-soluble resist 540 is deposited using a technique selected from a group consisting of: screen printing, lamination, stencil printing, imprinting, and inkjet printing. In some implementations, the water-soluble resist 540 is deposited using screen printing. The water-soluble resist 540 is placed and arranged according to a predetermined pattern on the piezoelectric layer 530 without using applying lithography and without applying a hard mask.

In FIG. 5C, the piezoelectric layer 530 is etched using a wet etchant to form a patterned piezoelectric coating 535 over the plurality of TFT circuits 525. The piezoelectric layer 530 is patterned by wet etching to form the patterned piezoelectric coating 535. The water-soluble resist 540 is retained during wet etching and serves as a mask in patterning the piezoelectric layer 530. The wet etchant may be a pure or hybrid hydrophobic wet etchant that is selective to the piezoelectric layer 530 but non-selective to the water-soluble resist 540. In some implementations, the patterned piezoelectric coating 535 has a taper angle between about 30 degrees and about 70 degrees after wet etching. In some implementations, the patterned piezoelectric coating 535 is formed without an undercut after wet etching.

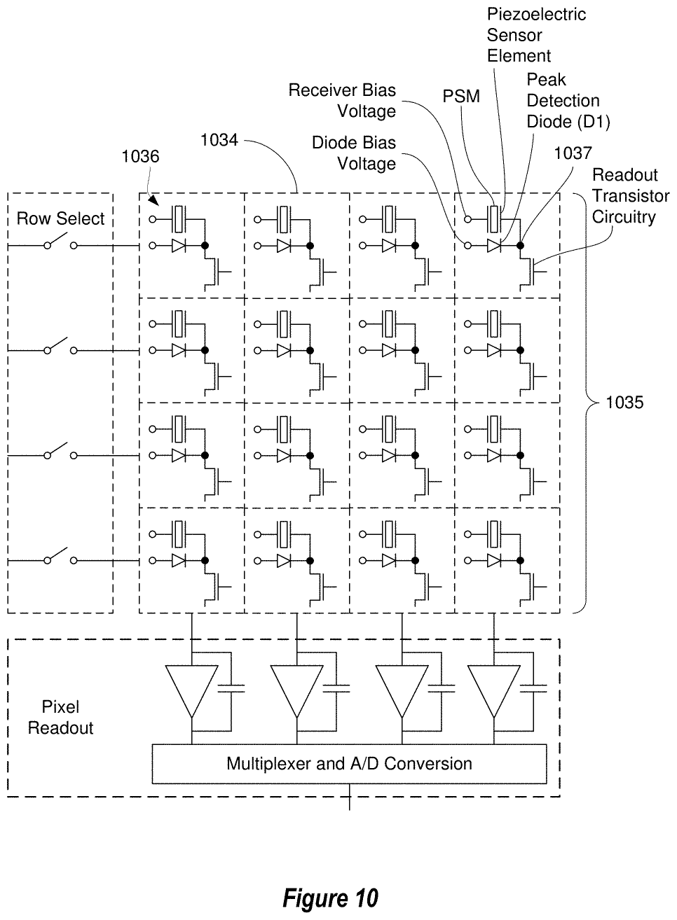

In FIG. 5D, the water-soluble resist 540 is removed using a water-based stripping process. The water-based stripping process removes the water-soluble resist 540 without contaminating or damaging the patterned piezoelectric coating 535. Thus, the patterned piezoelectric coating 535 is free or substantially free of contaminants. In some implementations, the partially fabricated device 500 may be implemented in any device, apparatus, or system that includes a biometric system as disclosed herein for ultrasonic sensing. An accompanying description of ultrasonic sensor systems may be described, for example, in FIGS. 9, 10, and 11A-11B.

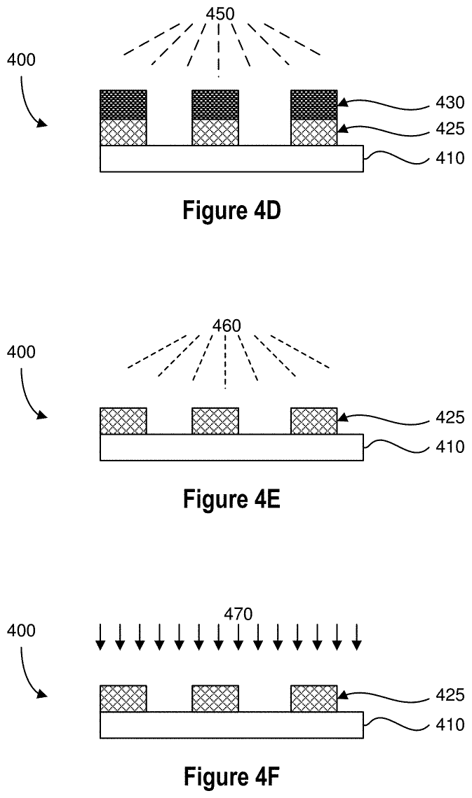

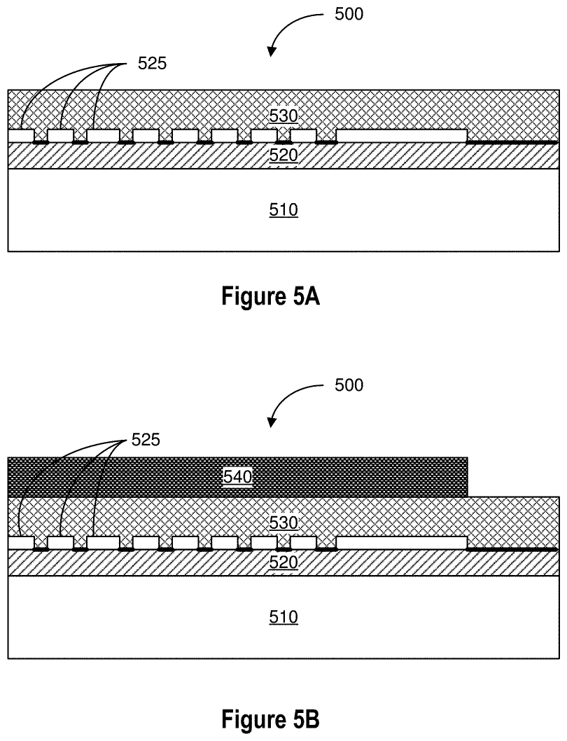

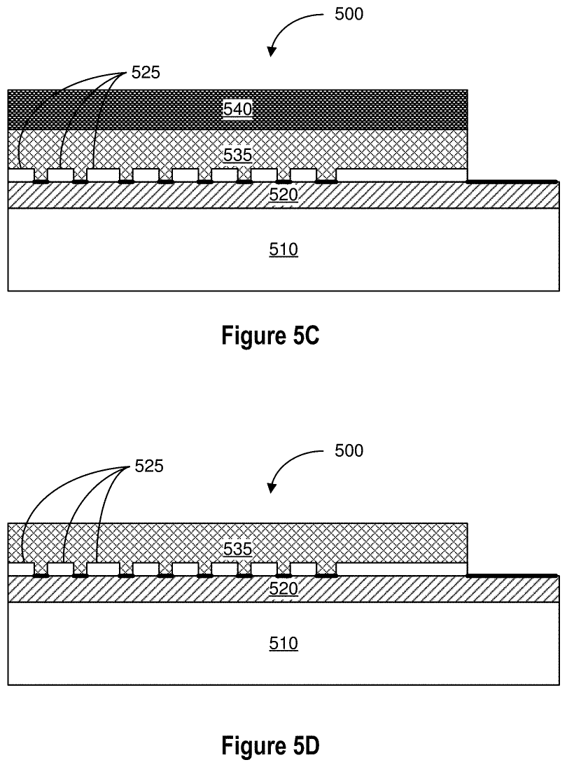

In the present disclosure, the water-soluble resist is deposited under certain conditions and with a composition and thickness that promote strong adhesion to a surface of the organic film. The interface adhesion of the water-soluble resist prevents peel-off during wet etching and prevents undercutting due to lateral etching through an interface between the water-soluble resist and the organic film. FIG. 6A shows an SEM image illustrating good adhesion of an example water-soluble resist on an organic film after wet etching. FIG. 6B shows an exploded view of the SEM image of FIG. 6A. The water-soluble resist exhibits good wetting characteristics on the organic film. After wet etching, the water-soluble resist is retained without peel-off as shown in FIGS. 6A and 6B. However, it is possible that certain conditions, certain compositions, and/or certain thicknesses of the water-soluble resist may contribute to peel-off. FIG. 6C shows an SEM image illustrating poor adhesion of an example water-soluble resist on an organic film after wet etching. This leads to pattern deformation of the organic film after wet etching as shown in FIG. 6C.

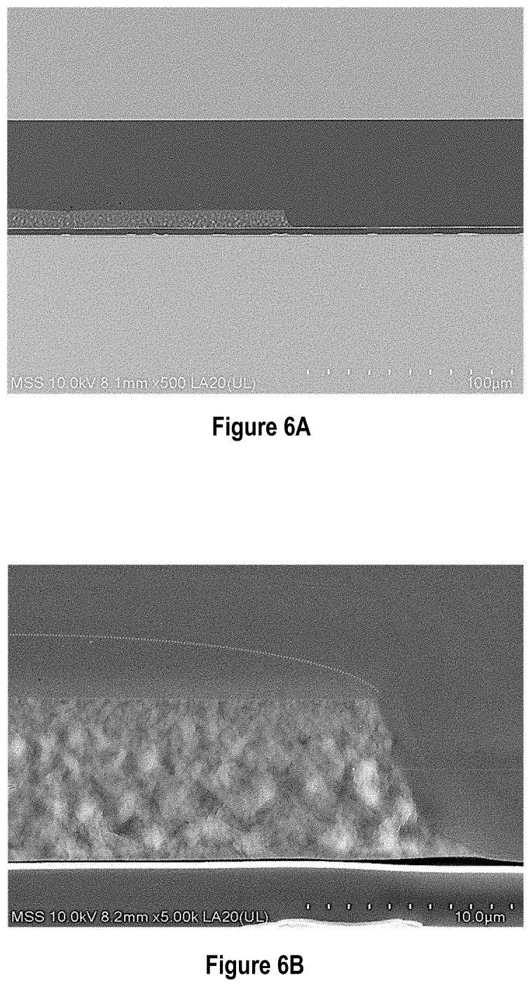

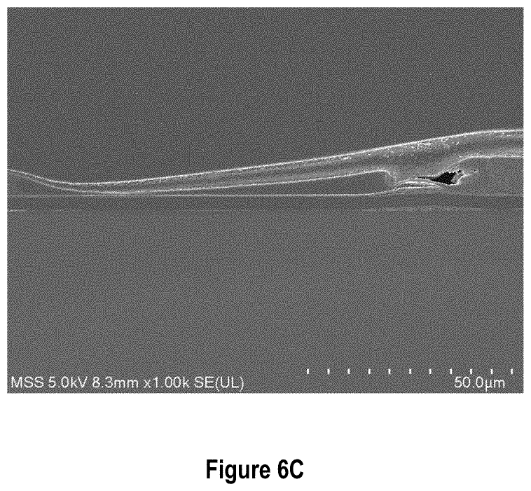

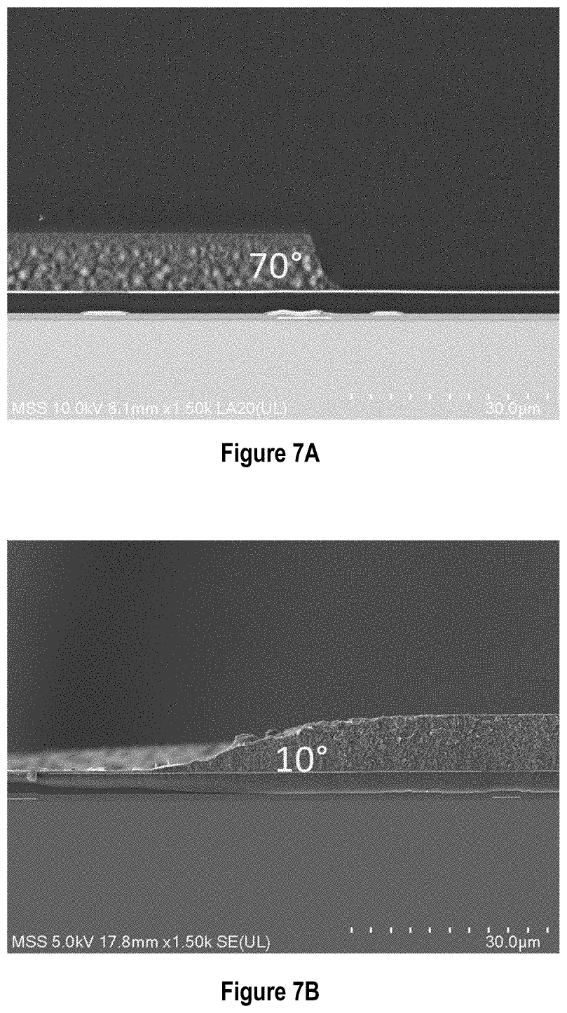

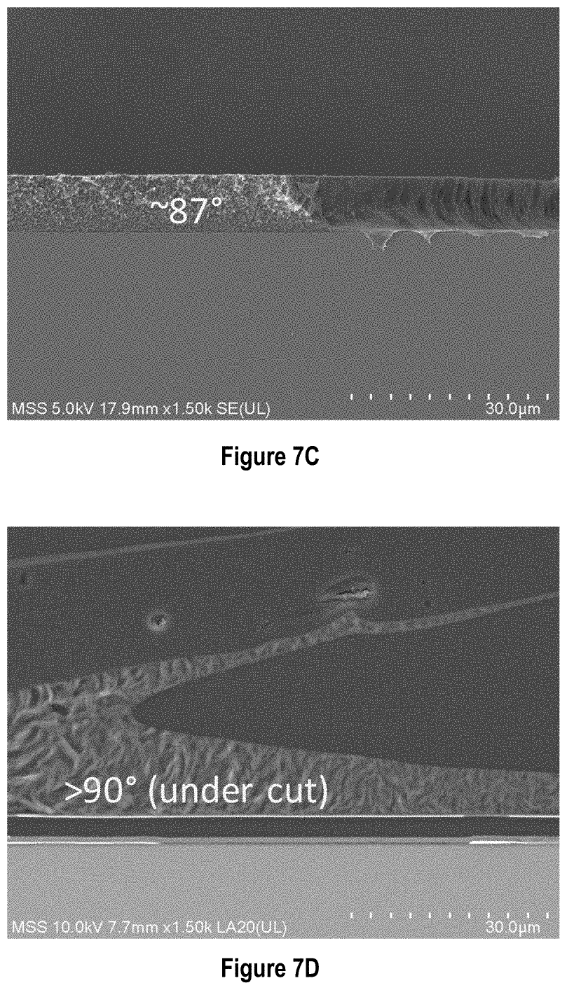

In the present disclosure, a taper angle may be controlled during wet etching using the water-soluble resist. The taper angle may facilitate deposition of subsequent materials and provide desirable step coverage. Selection of the wet etchant formulation and wet etchant conditions may result in a desirable taper for profile control. In addition, selection of the water-soluble resist composition and thickness may influence profile control. In some implementations, a desirable taper angle may be between about 5 degrees and about 85 degrees, or between about 10 degrees, and about 80 degrees, or between about 30 degrees and about 70 degrees. FIG. 7A shows an SEM image illustrating an etching profile of 70 degrees for an example organic film after wet etching. This may constitute an example of good etching profile control by the water-soluble resist and wet etchant. FIG. 7B shows an SEM image illustrating an etching profile of 10 degrees for an example organic film after wet etching. This may constitute an example of good etching profile control by the water-soluble resist and wet etchant. FIG. 7C shows an SEM image illustrating an etching profile of 87 degrees for an example organic film after wet etching. This may constitute an example of poor etching profile control by the water-soluble resist and wet etchant. FIG. 7D shows an SEM image illustrating an etching profile greater than 90 degrees with an undercut for an example organic film after wet etching. This may constitute an example of poor etching profile control by the water-soluble resist and wet etchant.

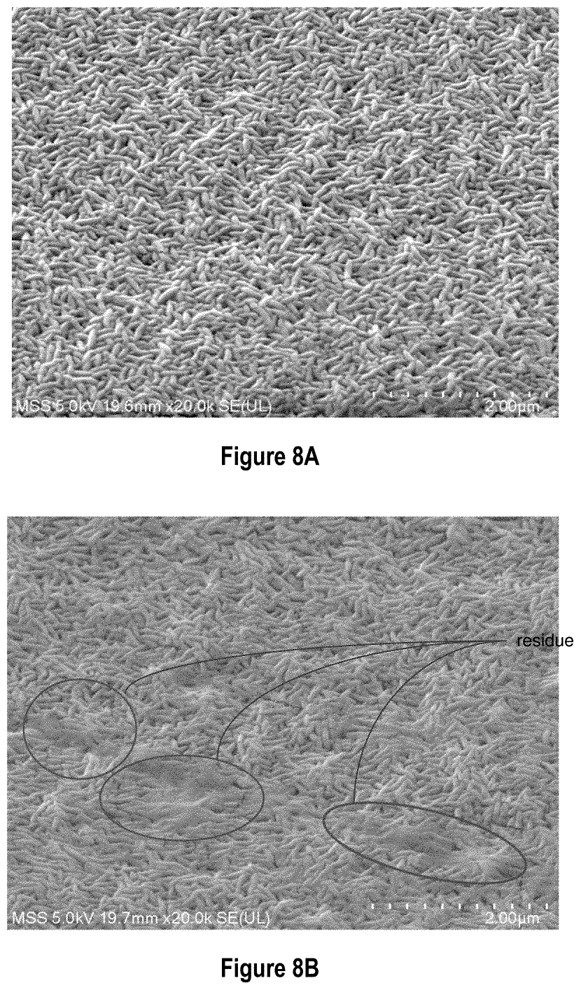

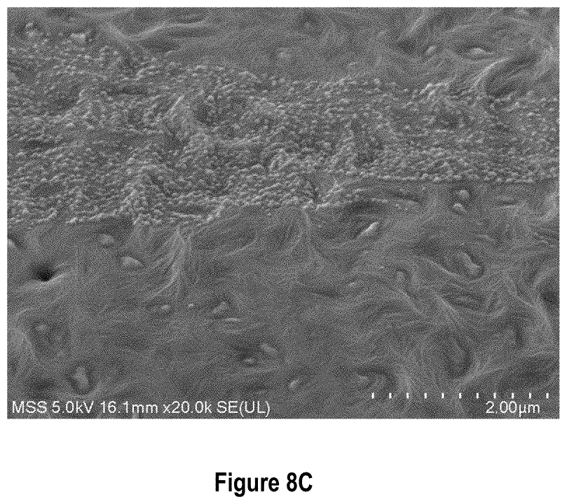

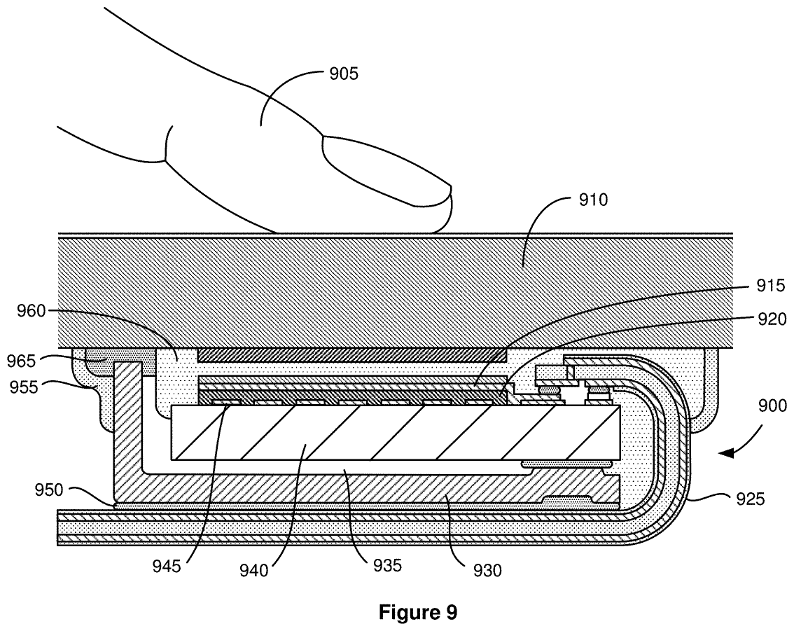

In the present disclosure, chemical resistance of the water-soluble resist may prevent contamination and damage to the underlying organic film after wet etching and stripping. Appropriate selection of the water-soluble resist composition as well as appropriate selection of the wet etchant and stripper may limit contamination and damage to the organic film. FIG. 8A shows an SEM image illustrating good crystalline morphology of an example piezoelectric material surface without residue after wet etching and resist stripping. This shows that the water-soluble resist effectively prevented contamination and damage to the organic film (e.g., piezoelectric material). FIG. 8B shows an SEM image illustrating crystalline morphology of an example piezoelectric material surface with residue after wet etching and resist stripping. After stripping, the water-soluble resist may leave unwanted resist residue, which can lead to problems related to device yield and reliability. FIG. 8C shows an SEM image illustrating poor crystalline morphology of an example piezoelectric material surface after wet etching and resist stripping. After wet etching and stripping, poor chemical resistance of the water-soluble resist may cause damage to the organic film (e.g., piezoelectric material). The damage may result in fused crystalline morphology, which adversely impacts film quality.

FIG. 9 shows a cross-sectional schematic view of an example ultrasonic fingerprint sensor system including a sensor substrate and piezoelectric layer. In FIG. 9, an ultrasonic sensor system 900 is located underneath or underlying a platen 910. The platen 910 may be deemed “in front of,” “above,” or “overlying” the ultrasonic sensor system 900, and the ultrasonic sensor system 900 may be deemed “behind,” “below,” or “underlying” the platen 910. Such terms as used herein are relative terms depending on the orientation of the device. In some implementations, the ultrasonic sensor system 900 is coupled to the platen 910 by a first adhesive 960. A finger 905 may press against the platen 910 to activate the ultrasonic sensor system 900. In some implementations, the platen 910 may be a cover glass of a display device (e.g., mobile device). In some implementations, the platen 910 may include a portion of a display such as an organic light-emitting diode (OLED) or active matrix organic light-emitting diode (AMOLED) display.

The ultrasonic sensor system 900 may include a sensor substrate 940, a plurality of sensor circuits 945 disposed on the sensor substrate 940, a piezoelectric layer 920, and an electrode layer 915. The ultrasonic sensor system 900 may further include a passivation layer (not shown). Different implementations may use different materials for the sensor substrate 940. For example, the sensor substrate 940 may include a silicon substrate, a silicon-on-insulator (SOI) substrate, a thin-film transistor (TFT) substrate, a glass substrate, a plastic substrate, a ceramic substrate, and/or a combination thereof.

The plurality of sensor circuits 945 may be formed over or on the sensor substrate 940, such as TFT circuits formed on a TFT substrate or complementary metal-oxide-semiconductor (CMOS) circuits formed on or in a silicon substrate. In some implementations, the piezoelectric layer 920 may be positioned over the plurality of sensor circuits 945. The piezoelectric layer 920 may serve as both a transmitter and a receiver of acoustic waves (e.g., ultrasonic waves), where the piezoelectric layer 920 is configured to transmit at least one acoustic wave/signal and receive or detect at least one acoustic wave/signal. The piezoelectric layer 920 may be made of one or more organic materials, where the piezoelectric layer 920 may be patterned to coat the plurality of sensor circuits 945 using a patterning process as described in the present disclosure.

The plurality of sensor circuits 945 may include an array of thin-film transistor circuits. For example, the sensor circuits 945 may include an array of pixel circuits, where each pixel circuit may include one or more TFTs. A pixel circuit may be configured to convert an electric charge generated by the transceiver layer proximate to the pixel circuit into an electrical signal in response to a received acoustic wave. Output signals from the sensor circuits 945 may be sent to a controller or other circuitry for signal processing.

In some implementations, the electrode layer 915 may be disposed, positioned, placed, or formed over the piezoelectric layer 920. The electrode layer 915 may include one or more electrically conductive layers/traces that are coupled to the piezoelectric layer 920. In some implementations, the electrode layer 915 may include silver ink. In some implementations, the electrode layer 915 may include copper, aluminum, nickel, or combinations thereof. Ultrasonic waves may be generated and transmitted by providing an electrical signal to the electrode layer 915. In addition, a passivation layer (not shown) may be disposed, positioned, placed, or formed over at least portions of the electrode layer 915. The passivation layer may include one or more layers of electrically insulating material. The sensor substrate 940 and sensor circuits 945, the piezoelectric layer 920 and the electrode layer 915 may be positioned under a platen 910.

A printed circuit 925 may be coupled to the sensor substrate 940. The printed circuit 925 may be a flexible printed circuit. The printed circuit 925 may include one or more dielectric layers and one or more interconnects (e.g., traces, vias and pads). In some implementations, the printed circuit 925 may be electrically coupled to a controller or other circuitry for signal processing of signals to/from the sensor circuits 945.

The ultrasonic sensor system 900 may be attached to the platen 910 using a first adhesive 960 and an edge sealant 955. The ultrasonic sensor system 900 may further include a sensor housing or cap 930 for protecting the ultrasonic sensor system 900. The sensor housing 930 may be coupled to a portion of the platen 910 via a second adhesive 965 and may be coupled to a portion of the sensor substrate 940 and to a portion of the printed circuit 925 via a third adhesive 950. In some implementations, the sensor housing 930 may be largely cantilevered over the active area of the sensor substrate 940. The sensor housing 930 may be coupled to the sensor substrate 940 such that a cavity 935 is formed between the back side of the sensor substrate 940 and the sensor housing 930. In some implementations, the sensor housing 930 may include one or more layers of plastic or metal.

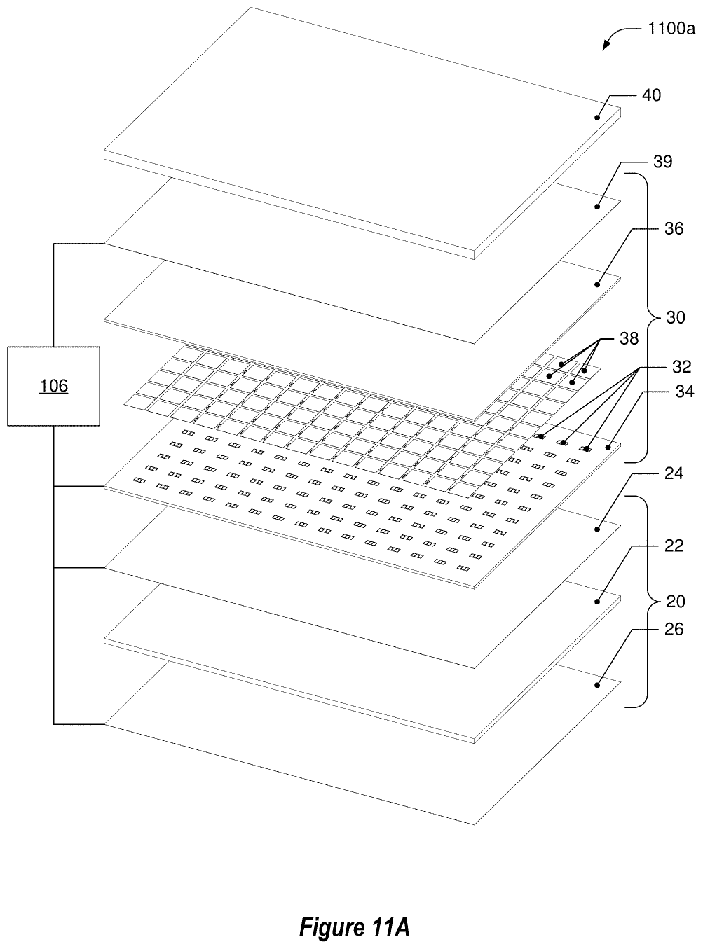

FIG. 10 shows a schematic diagram of an example 4 x 4 pixel array of sensor pixels for an ultrasonic fingerprint sensor system. Each pixel 1034 may be, for example, associated with a local region of piezoelectric sensor material (PSM), a peak detection diode (D1) and a readout transistor (M3); many or all of these elements may be formed on or in a substrate to form the pixel circuit 1036. In practice, the local region of piezoelectric sensor material of each pixel 1034 may transduce received ultrasonic energy into electrical charges. The peak detection diode D1 may register the maximum amount of charge detected by the local region of piezoelectric sensor material PSM. Each row of the pixel array 1035 may then be scanned, e.g., through a row select mechanism, a gate driver, or a shift register, and the readout transistor M3 for each column may be triggered to allow the magnitude of the peak charge for each pixel 1034 to be read by additional circuitry, e.g., a multiplexer and an A/D converter. The pixel circuit 1036 may include one or more TFTs to allow gating, addressing, and resetting of the pixel 1034.

Each pixel circuit 1036 may provide information about a small portion of the object detected by the ultrasonic sensor system. While, for convenience of illustration, the example shown in FIG. 10 is of a relatively coarse resolution, ultrasonic sensors having a resolution on the order of 500 pixels per inch or higher may be configured with an appropriately scaled structure. The detection area of the ultrasonic sensor system may be selected depending on the intended object of detection. For example, the detection area may range from about 5 mm×5 mm for a single finger to about 3 inches×3 inches for four fingers. Smaller and larger areas, including square, rectangular and non-rectangular geometries, may be used as appropriate for the target object.

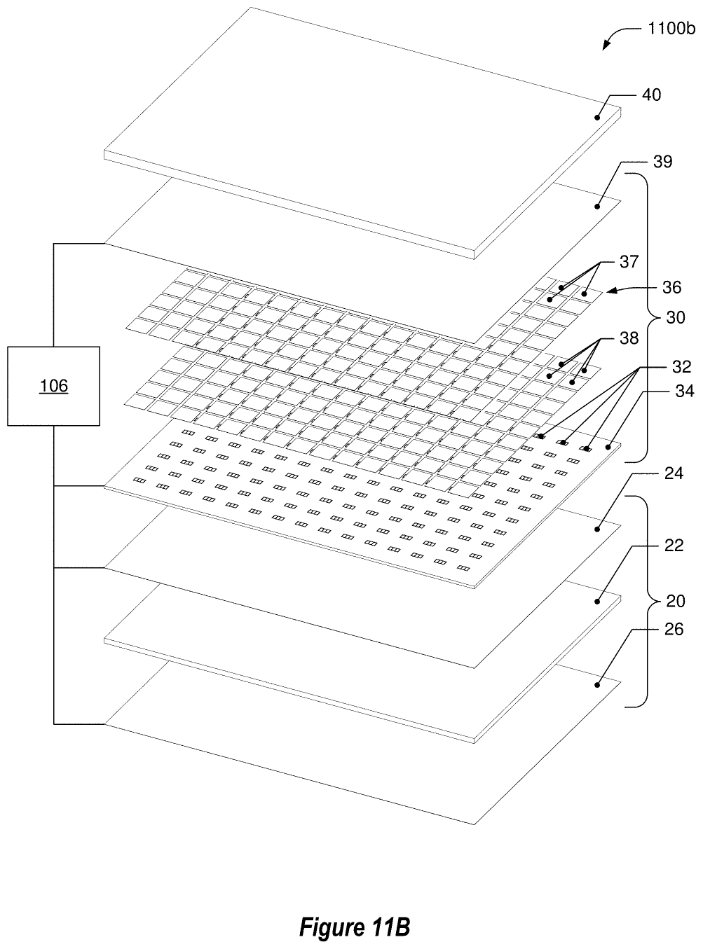

FIG. 11A shows an example of an exploded view of an ultrasonic sensor system. In this example, the ultrasonic sensor system 1100a includes an ultrasonic transmitter 20 and an ultrasonic receiver 30 under a platen 40. The ultrasonic transmitter 20 may include a substantially planar piezoelectric transmitter layer 22 and may be capable of functioning as a plane wave generator. Ultrasonic waves may be generated by applying a voltage to the piezoelectric layer to expand or contract the layer, depending upon the signal applied, thereby generating a plane wave. In this example, a control system 106 may be capable of causing a voltage that may be applied to the planar piezoelectric transmitter layer 22 via a first transmitter electrode 24 and a second transmitter electrode 26. In this fashion, an ultrasonic wave may be made by changing the thickness of the layer via a piezoelectric effect. This ultrasonic wave may travel towards a finger (or other object to be detected), passing through the platen 40. A portion of the wave not absorbed or transmitted by the object to be detected may be reflected so as to pass back through the platen 40 and be received by at least a portion of the ultrasonic receiver 30. The first and second transmitter electrodes 24 and 26 may be metallized electrodes, for example, metal layers that coat opposing sides of the piezoelectric transmitter layer 22.

The ultrasonic receiver 30 may include an array of sensor pixel circuits 32 disposed on a substrate 34, which also may be referred to as a backplane, and a piezoelectric receiver layer 36. In some implementations, each sensor pixel circuit 32 may include one or more TFT elements, electrical interconnect traces and, in some implementations, one or more additional circuit elements such as diodes, capacitors, and the like. Each sensor pixel circuit 32 may be configured to convert an electric charge generated in the piezoelectric receiver layer 36 proximate to the pixel circuit into an electrical signal. Each sensor pixel circuit 32 may include a pixel input electrode 38 that electrically couples the piezoelectric receiver layer 36 to the sensor pixel circuit 32.

In the illustrated implementation, a receiver bias electrode 39 is disposed on a side of the piezoelectric receiver layer 36 proximal to platen 40. The receiver bias electrode 39 may be a metallized electrode and may be grounded or biased to control which signals may be passed to the array of sensor pixel circuits 32. Ultrasonic energy that is reflected from the exposed (top) surface of the platen 40 may be converted into localized electrical charges by the piezoelectric receiver layer 36. These localized charges may be collected by the pixel input electrodes 38 and passed on to the underlying sensor pixel circuits 32. The charges may be amplified or buffered by the sensor pixel circuits 32 and provided to the control system 106.

The control system 106 may be electrically connected (directly or indirectly) with the first transmitter electrode 24 and the second transmitter electrode 26, as well as with the receiver bias electrode 39 and the sensor pixel circuits 32 on the substrate 34. In some implementations, the control system 106 may be capable of processing the amplified signals received from the sensor pixel circuits 32.

The control system 106 may be capable of controlling the ultrasonic transmitter 20 and/or the ultrasonic receiver 30 to obtain ultrasonic image data, e.g., by obtaining fingerprint images. Whether or not the ultrasonic sensor system 1100a includes an ultrasonic transmitter 20, the control system 106 may be capable of obtaining attribute information from the ultrasonic image data. In some examples, the control system 106 may be capable of controlling access to one or more devices based, at least in part, on the attribute information. The ultrasonic sensor system 1100a (or an associated device) may include a memory system that includes one or more memory devices. In some implementations, the control system 106 may include at least a portion of the memory system. The control system 106 may be capable of obtaining attribute information from ultrasonic image data and storing the attribute information in the memory system. In some implementations, the control system 106 may be capable of capturing a fingerprint image, obtaining attribute information from the fingerprint image and storing attribute information obtained from the fingerprint image (which may be referred to herein as fingerprint image information) in the memory system. According to some examples, the control system 106 may be capable of capturing a fingerprint image, obtaining attribute information from the fingerprint image and storing attribute information obtained from the fingerprint image even while maintaining the ultrasonic transmitter 20 in an “off” state.

In some implementations, the control system 106 may be capable of operating the ultrasonic sensor system 1100a in an ultrasonic imaging mode or a force-sensing mode. In some implementations, the control system 106 may be capable of maintaining the ultrasonic transmitter 20 in an “off” state when operating the ultrasonic sensor system in a force-sensing mode. The ultrasonic receiver 30 may be capable of functioning as a force sensor when the ultrasonic sensor system 1100a is operating in the force-sensing mode. In some implementations, the control system 106 may be capable of controlling other devices, such as a display system, a communication system, etc. In some implementations, the control system 106 may be capable of operating the ultrasonic sensor system 1100a in a capacitive imaging mode.

The platen 40 may be any appropriate material that can be acoustically coupled to the receiver, with examples including plastic, ceramic, sapphire, metal and glass. In some implementations, the platen 40 may be a cover plate, e.g., a cover glass or a lens glass for a display. Particularly when the ultrasonic transmitter 20 is in use, fingerprint detection and imaging can be performed through relatively thick platens if desired, e.g., 3 mm and above. However, for implementations in which the ultrasonic receiver 30 is capable of imaging fingerprints in a force detection mode or a capacitance detection mode, a thinner and relatively more compliant platen 40 may be desirable. According to some such implementations, the platen 40 may include one or more polymers, such as one or more types of parylene, and may be substantially thinner. In some such implementations, the platen 40 may be tens of microns thick or even less than 10 microns thick.

Examples of piezoelectric materials that may be used to form the piezoelectric receiver layer 36 include piezoelectric polymers having appropriate acoustic properties, for example, an acoustic impedance between about 2.5 MRayls and 5 MRayls. Specific examples of piezoelectric materials that may be employed include ferroelectric polymers such as polyvinylidene fluoride (PVDF) and polyvinylidene fluoride-trifluoroethylene (PVDF-TrFE) copolymers. Examples of PVDF copolymers include 60:40 (molar percent) PVDF-TrFE, 70:30 PVDF-TrFE, 80:20 PVDF-TrFE, and 90:10 PVDR-TrFE. Other examples of piezoelectric materials that may be employed include polyvinylidene chloride (PVDC) homopolymers and copolymers, polytetrafluoroethylene (PTFE) homopolymers and copolymers, and diisopropylammonium bromide (DIPAB).

The thickness of each of the piezoelectric transmitter layer 22 and the piezoelectric receiver layer 36 may be selected so as to be suitable for generating and receiving ultrasonic waves. In one example, a PVDF planar piezoelectric transmitter layer 22 is approximately 28 μm thick and a PVDF-TrFE receiver layer 36 is approximately 12 μm thick. Example frequencies of the ultrasonic waves may be in the range of 5 MHz to 30 MHz, with wavelengths on the order of a millimeter or less.

FIG. 11B shows an exploded view of an alternative example of an ultrasonic sensor system. In this example, the piezoelectric receiver layer 36 has been formed into discrete elements 37. In the implementation shown in FIG. 11B, each of the discrete elements 37 corresponds with a single pixel input electrode 38 and a single sensor pixel circuit 32. However, in alternative implementations of the ultrasonic sensor system 1100b, there is not necessarily a one-to-one correspondence between each of the discrete elements 37, a single pixel input electrode 38 and a single sensor pixel circuit 32. For example, in some implementations there may be multiple pixel input electrodes 38 and sensor pixel circuits 32 for a single discrete element 37.

FIGS. 11A and 11B show example arrangements of ultrasonic transmitters and receivers in an ultrasonic sensor system, with other arrangements being possible. For example, in some implementations, the ultrasonic transmitter 20 may be above the ultrasonic receiver 30 and therefore closer to the object(s) to be detected. In some implementations, the ultrasonic transmitter may be included with the ultrasonic sensor array (e.g., a single-layer transmitter and receiver). In some implementations, the ultrasonic sensor system may include an acoustic delay layer. For example, an acoustic delay layer may be incorporated into the ultrasonic sensor system between the ultrasonic transmitter 20 and the ultrasonic receiver 30. An acoustic delay layer may be employed to adjust the ultrasonic pulse timing, and at the same time electrically insulate the ultrasonic receiver 30 from the ultrasonic transmitter 20. The acoustic delay layer may have a substantially uniform thickness, with the material used for the delay layer and/or the thickness of the delay layer selected to provide a desired delay in the time for reflected ultrasonic energy to reach the ultrasonic receiver 30. In doing so, the range of time during which an energy pulse that carries information about the object by virtue of having been reflected by the object may be made to arrive at the ultrasonic receiver 30 during a time range when it is unlikely that energy reflected from other parts of the ultrasonic sensor system is arriving at the ultrasonic receiver 30. In some implementations, the substrate 34 and/or the platen 40 may serve as an acoustic delay layer.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor or any conventional processor, controller, microcontroller or state machine. A processor may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, the structures disclosed in this specification and their structural equivalents thereof, or in any combination thereof. Implementations of the subject matter described in this specification may be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium, such as a non-transitory medium. The processes of a method or algorithm disclosed herein may be implemented in a processor-executable software module that may reside on a computer-readable medium. Computer-readable media include both computer storage media and communication media including any medium that may be enabled to transfer a computer program from one place to another. Storage media may be any available media that may be accessed by a computer. By way of example and not limitation, non-transitory media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those having ordinary skill in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein.

Certain features that are described in this specification in the context of separate implementations may also be implemented in combination in a single implementation. Conversely, various features that are described in the context of a single implementation may also be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, other implementations are within the scope of the following claims. In some cases, the actions recited in the claims may be performed in a different order and still achieve desirable results.

It will be understood that unless features in any of the particular described implementations are expressly identified as incompatible with one another or the surrounding context implies that they are mutually exclusive and not readily combinable in a complementary and/or supportive sense, the totality of this disclosure contemplates and envisions that specific features of those complementary implementations may be selectively combined to provide one or more comprehensive, but slightly different, technical solutions. It will therefore be further appreciated that the above description has been given by way of example only and that modifications in detail may be made within the scope of this disclosure.

What is claimed is:

1. A method of patterning an organic layer of a substrate, the method comprising:
providing a substrate having an organic layer;
depositing a water-soluble resist over the organic layer, wherein the water-soluble resist is deposited by a technique selected from a group consisting of: screen printing, lamination, stencil printing, imprinting, and inkjet printing;
patterning the organic layer by wet etching to form a patterned organic structure; and
removing the water-soluble resist using water or water-based solvent.

2. The method of claim 1, wherein the organic layer includes a piezoelectric material.

3. The method of claim 2, wherein the piezoelectric material includes polyvinylidene fluoride (PVDF) polymer or polyvinylidene trifluoroethylene (PVDF-TrFE) copolymer, and wherein the substrate includes a plurality of thin film transistor (TFT) circuits, the piezoelectric material being positioned over the plurality of TFT circuits.

4. The method of claim 1, wherein the patterned organic structure has a taper angle between about 5 degrees and about 85 degrees after patterning the organic layer by wet etching.

5. The method of claim 4, wherein the patterned organic structure has a taper angle between about 30 degrees and about 70 degrees after patterning the organic layer by wet etching.

6. The method of claim 1, wherein the water-soluble resist adheres to the patterned organic structure after patterning the organic layer by wet etching.

7. The method of claim 1, wherein the patterned organic structure is free or substantially free of contaminants after patterning the organic layer by wet etching and removing the water-soluble resist.

8. The method of claim 1, wherein the patterned organic structure is formed without an undercut after patterning the organic layer by wet etching.

9. The method of claim 1, wherein the water-soluble resist includes a water-soluble polymer, wherein the water-soluble polymer includes polyvinyl alcohol (PVOH), polyethylene glycol (PEG), polyethylene oxide (PEO), or polyvinyl acetate (PVA).

10. The method of claim 1, wherein the water-soluble resist includes a filler, wherein the filler includes silica or a carbon-based filler, the water-soluble resist having 0.1-30 wt. % filler.

11. The method of claim 1, wherein the water-soluble resist includes a surfactant, the water-soluble resist having 0.1-30 wt. % surfactant.

12. The method of claim 1, wherein the water-soluble resist includes an inorganic salt, the water-soluble resist having 0.1-30 wt. % inorganic salt.

13. The method of claim 1, further comprising:
curing the water-soluble resist at an elevated temperature between about 50° C. and about 400° C. and for a duration between about 5 minutes and about 120 minutes prior to patterning the organic layer.

14. The method of claim 1, wherein patterning the organic layer comprises etching portions of the organic layer defined by the water-soluble resist with a wet etchant, the wet etchant including acetone, methyl ethyl ketone (MEK), glycol ether ester, dimethyl acetamide, or dimethyl sulfoxide.

15. The method of claim 1, wherein removing the water-soluble resist comprises stripping the water-soluble resist using water at a temperature between about 50° C. and about 200° C.

16. The method of claim 1, wherein the water-soluble resist has an average thickness between about 0.5 μm and about 50 μm.

17. The method of claim 1, wherein the water-soluble resist is deposited and patterned on the organic layer without applying lithography.

18. The method of claim 1, wherein the patterned organic structure is formed without applying a hard mask.

19. The method of claim 1, wherein the water-soluble resist is deposited and patterned on the organic layer by screen printing.

20. A device comprising:
a substrate having a plurality of TFT circuits;
a piezoelectric material coating over the plurality of TFT circuits, wherein the piezoelectric material coating is patterned by:
depositing a water-soluble resist over a piezoelectric layer by a technique selected from a group consisting of: screen printing, lamination, stencil printing, imprinting, and inkjet printing;
patterning the piezoelectric layer by wet etching to form the piezoelectric material coating; and
removing the water-soluble resist.

21. The device of claim 20, wherein the piezoelectric material coating has a taper angle between about 30 degrees and about 70 degrees, is free or substantially free of contaminants, and is formed without an undercut.

22. The device of claim 20, wherein the piezoelectric material coating is patterned without applying a hard mask or applying photolithography.
